(19) United States
(12) Patent Application Publication
(10) Pub. No.: US 2026/0332116 A1
(43) Pub. Date: Oct. 22, 2026

(54) RECEIVER CIRCUITS

(71) Applicant: Realtek Semiconductor Corp., HsinChu (TW)

(72) Inventors: I-Ju Chen, HsinChu (TW); Kuan-Yu Shih, HsinChu (TW)

(73) Assignee: Realtek Semiconductor Corp., HsinChu (TW)

(21) Appl. No.: 19/577,339

(22) Filed: Mar. 24, 2026

(30) Foreign Application Priority Data
Apr. 18, 2025 (TW) 114114700

(51) Int. Cl. H03G 3/30; H03F 1/56; H03F 3/19

(52) U.S. Cl. CPC H03G 3/3036; H03F 1/56; H03F 3/19; H03F 2200/387; H03F 2200/451; H03G 2201/103; H03G 2201/307

(57) ABSTRACT

A receiver circuit includes a first amplifier circuit, a mixer, a second amplifier circuit, a compensation circuit, and a controller circuit. The first amplifier circuit processes a reception signal according to a first gain to generate a first amplification signal. The mixer receives the first amplification signal, and performs a frequency conversion operation upon the first amplification signal according to an oscillation signal to generate a frequency-converted signal. The second amplifier circuit receives the frequency-converted signal, and processes the frequency-converted signal according to a second gain to generate a second amplification signal. The compensation circuit coupled to an output terminal of the first amplifier circuit provides an impedance at the output terminal of the first amplifier circuit. The controller circuit is coupled to the compensation circuit and the second amplifier circuit, and controls the compensation circuit to correspondingly adjust the impedance in response to an adjustment of the second gain.

### BACKGROUND OF THE INVENTION

### 1.Field of the Invention

The present invention is related to a receiver circuit, and more particularly, to a compensation circuit compensating for in-phase and quadrature phase (IQ) imbalance within the receiver circuit and an associated method.

### 2. DESCRIPTION OF THE PRIOR ART

Most modern radio frequency (RF) transceiver designs adopt a low intermediate frequency (low-IF) architecture. In this architecture, an IF difference exists between an RF signal and a local oscillating (LO) signal, which causes the issue of image signals to occur.

A receiver must reject image signal components contained in a reception signal as much as possible, in order to reduce interference between the image signals and the desired signal during signal processing. The image signal rejection capability of the receiver is referred to as an image rejection ratio (IMRR). The IMRR is related to gain imbalance and phase imbalance between an in-phase (I) channel and a quadrature (Q) channel of the receiver. In addition, the gain values of amplifiers used during the signal processing in the receiver also affect the IQ imbalance, meaning the ability of the receiver to compensate for the IQ imbalance is critical to improving the IMRR.

Therefore, a compensation circuit and an associated method for effectively compensating for the IQ imbalance in order to improve the IMRR i while maintaining flexibility in adjusting the gain at a reception terminal are urgently needed.

### SUMMARY OF THE INVENTION

It is therefore one of the objectives of the present invention to provide receiver circuits including a compensation circuit which can compensate for IQ imbalance, in order to address the above-mentioned issues.

According to an embodiment of the present invention, a receiver circuit is provided. The receiver circuit comprises a first amplifier circuit, a mixer, a second amplifier circuit, a compensation circuit, and a controller circuit. The first amplifier circuit is arranged to process a reception signal according to a first gain in order to generate a first amplification signal. The mixer is arranged to receive the first amplification signal, and perform a frequency conversion operation upon the first amplification signal according to an oscillation signal in order to generate a frequency-converted signal. The second amplifier circuit is arranged to receive the frequency-converted signal, and process the frequency-converted signal according to a second gain in order to generate a second amplification signal. The compensation circuit is coupled to an output terminal of the first amplifier circuit, and is arranged to provide an impedance at the output terminal of the first amplifier circuit, wherein the impedance is a variable impedance. The controller circuit is coupled to the compensation circuit and the second amplifier circuit, and is arranged to control the compensation circuit to correspondingly adjust the impedance in response to an adjustment of the second gain.

According to an embodiment of the present invention, a receiver circuit is provided. The receiver circuit comprises a first amplifier circuit, a mixer, a second amplifier circuit, a compensation circuit, and a controller circuit. The first amplifier circuit is arranged to process a reception signal according to a first gain in order to generate a first amplification signal. The mixer is arranged to receive the first amplification signal, and perform a frequency conversion operation upon the first amplification signal according to an oscillation signal in order to generate a frequency-converted signal. The second amplifier circuit is arranged to receive the frequency-converted signal, and process the frequency-converted signal according to a second gain in order to generate a second amplification signal. The compensation circuit is coupled to an output terminal of the first amplifier circuit, and is arranged to provide an impedance at the output terminal of the first amplifier circuit, wherein the impedance is a variable impedance. The controller circuit is coupled to the first amplifier circuit, the compensation circuit, and the second amplifier circuit, and is arranged to control the compensation circuit to correspondingly adjust the impedance in response to an adjustment of the first gain or an adjustment of the second gain.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a receiver circuit according to an embodiment of the present invention.

FIG. 2 is a diagram illustrating a receiver circuit according to an embodiment of the present invention.

FIG. 3 is a flow chart of a method of compensating for IQ imbalance in a receiver circuit according to an embodiment of the present invention.

### DETAILED DESCRIPTION

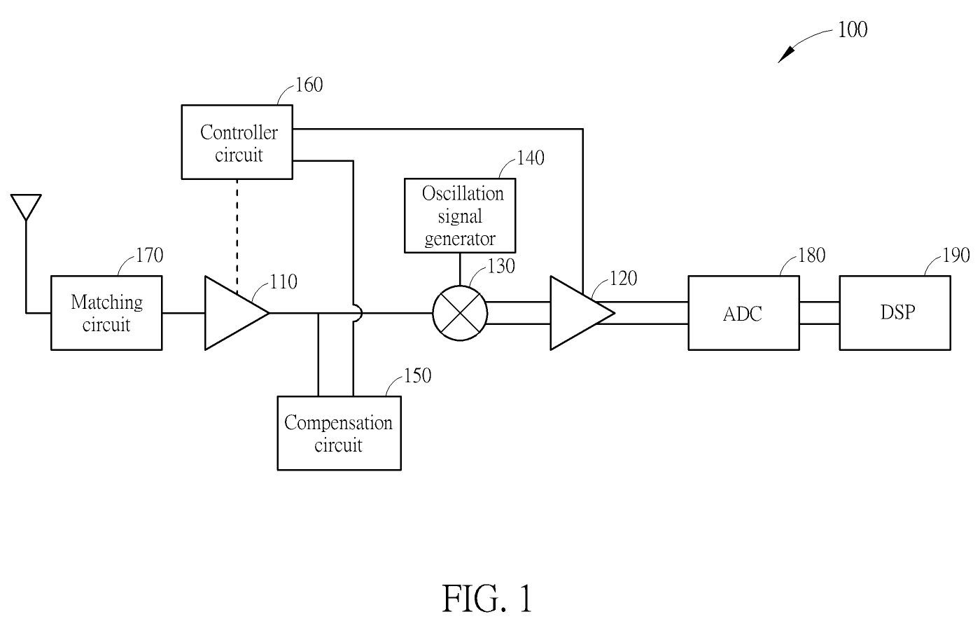

FIG. 1 is a block diagram of a receiver circuit 100 according to an embodiment of the present invention. The receiver circuit 100 may receive signals via an antenna, and may include a matching circuit 170, an amplifier circuit 110, a mixer 130, an amplifier circuit 120, an analog-to-digital converter (ADC) 180, and a digital signal processor (DSP) 190 configured in sequence along a signal processing path.

According to an embodiment of the present invention, the matching circuit 170 may provide input impedance matching for the amplifier circuit 110. The amplifier circuit 110 may process a reception signal according to a first gain in order to generate a first amplification signal. The mixer 130 may receive the first amplification signal from the amplifier circuit 110, receive an oscillation signal from an oscillation signal generator 140 included in the receiver circuit 100, and perform a frequency conversion operation (e.g., a frequency down-conversion operation) upon the first amplification signal according to the oscillation signal in order to generate a frequency-converted signal.

The amplifier circuit 120 may receive the frequency-converted signal from the mixer 130, and process the frequency-converted signal according to a second gain in order to generate a second amplification signal. The ADC 180 may receive the second amplification signal from the amplifier circuit 120, and convert the second amplification signal from an analog signal into a digital signal. The DSP 190 may receive the digital signal from the ADC 180, and process the digital signal to obtain a required signal.

The characteristic variations of the analog circuit components in the receiver circuit 100 may cause gain imbalance or phase imbalance between an in-phase (I) channel and a quadrature (Q) channel along the signal processing path. For example, component characteristic differences between the I channel and the Q channel of the amplifier circuit 120, the mixer 130, and the oscillation signal generator 140 may result in IQ imbalance. In addition, gain adjustment of the amplifier circuits 110 and 120 may also affect the IQ imbalance along the signal processing path.

In order to accurately calibrate the IQ imbalance of the reception side (e.g., by performing signal processing to compensate for or cancel the IQ imbalance), the receiver circuit 100 may first operate in a pre-calibration mode to estimate parameters associated with the IQ imbalance calibration.

Specifically, in the pre-calibration mode, a power amplifier of a transmitter circuit (not shown in FIG. 1) may be turned off, and a radio frequency (RF) signal generated by the transmitter circuit may be coupled to the reception side (i.e., the receiver circuit 100) as a reception signal. After the reception signal is processed by the analog circuits along the signal processing path, the reception signal is provided to the DSP 190 for performing digital signal processing and estimating parameters required to compensate for the IQ imbalance.

Afterwards, the receiver circuit 100 may operate in a reception mode. In the reception mode, the receiver circuit 100 may normally receive an RF signal from a radio interface via an antenna as a reception signal and process the reception signal, wherein the signal processing includes operations of calibrating the IQ imbalance according to the parameters estimated in the pre-calibration mode.

In the pre-calibration mode, the receiver circuit 100 may operate according to a specific gain setting. For example, the gains of the amplifier circuits 110 and 120 may be set as specific levels for performing the pre-calibration. In the reception mode, however, the gain setting of the amplifier circuits 110 and 120 must be adjusted according to requirements of actual communications environments. For example, by changing the gain of the amplifier circuit 110 or 120, the overall system gain of the reception side can be adjusted. After the gain setting of the amplifier circuit 110 or 120 is adjusted, the parameters estimated in the pre-calibration mode for calibrating the IQ imbalance will not necessarily yield an optimal result, which causes the image rejection ratio of the receiver circuit 100 to decrease.

Since the reception signal processing path and the IQ imbalance calibration path of the receiver circuit 100 are identical, the gain switching of the amplifier circuits 110 and 120 is inevitably restricted to avoid affecting the effectiveness of IQ imbalance calibration. That is, achieving better IQ imbalance calibration performance limits the flexibility of gain adjustment in the amplifier circuits. In addition, in order to achieve better IQ imbalance calibration under different gain settings, it would be necessary to increase the number of calibration operations performed in the pre-calibration mode in order to estimate the parameters corresponding to other gain settings, which may significantly increase the calibration workload.

In order to allow the receiver circuit 100 to freely adjust the gain of the amplifier circuits in the reception mode without increasing the number of calibration operations and without affecting the effectiveness of IQ imbalance calibration, the present invention proposes a compensation circuit and an associated method capable of effectively compensating for the IQ imbalance. In this way, a good image rejection ratio can be maintained, which causes the receiver circuit to retain gain adjustment flexibility while maintaining excellent image rejection performance.

According to an embodiment of the present invention, the receiver circuit 100 may further include a compensation circuit 150 and a controller circuit 160. The compensation circuit 150 may be coupled to an output terminal of the amplifier circuit 110, and may provide an impedance at the output terminal of the amplifier circuit 110, wherein the impedance is a variable impedance (i.e., the impedance value can be adjusted dynamically). The controller circuit 160 may be coupled to the compensation circuit 150 and the amplifier circuit 120, and may control the compensation circuit 150 to correspondingly adjust the impedance provided at the output terminal of the amplifier circuit 110 in response to gain adjustment of the amplifier circuit 120 (i.e., adjustment of the second gain).

According to another embodiment of the present invention, the controller circuit 160 may be further coupled to the amplifier circuit 110 (shown as dashed lines in FIG. 1), and may control the compensation circuit 150 to correspondingly adjust the impedance provided at the output terminal of the amplifier circuit 110 in response to gain adjustment of the amplifier circuit 110 (i.e., adjustment of the first gain).

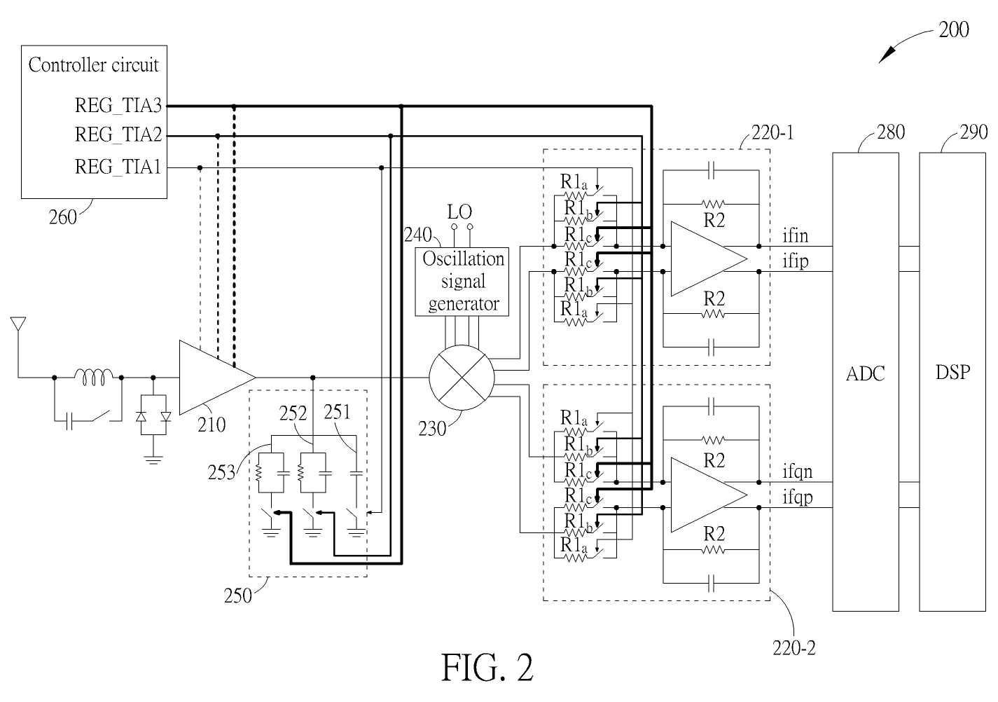

FIG. 2 is a diagram illustrating a receiver circuit 200 according to an embodiment of the present invention. The receiver circuit 200 may include amplifier circuits 210, 220-1, and 220-2, a mixer 230, an oscillation signal generator 240, a compensation circuit 250, a controller circuit 260, an ADC 280, a DSP 290, and a matching circuit that provides input impedance matching for the amplifier circuit 210.

According to an embodiment of the present invention, the amplifier circuit 210 may be a low noise amplifier (LNA) circuit, and the amplifier circuits 220-1 and 220-2 may be trans-impedance amplifier (TIA) circuits respectively configured on the I channel and the Q channel, but the present invention is not limited thereto.

According to an embodiment of the present invention, the amplifier circuit 210 may process a reception signal according to a first gain in order to generate a first amplification signal. The oscillation signal generator 240 may generate and provide multiple oscillation signals to the I channel and the Q channel according to a fundamental local oscillation signal LO. The mixer 230 may receive the first amplification signal from the amplifier circuit 210, receive the oscillation signals from the oscillation signal generator 240, and perform a frequency conversion operation (e.g., a frequency down-conversion operation) upon the first amplification signal according to the oscillation signals in order to generate multiple frequency-converted signals.

The amplifier circuit 220-1 on the I channel may receive the frequency-converted signals being a pair of differential signals from the mixer 230, and process the frequency-converted signals according to a second gain in order to generate multiple second amplification signals ifin and ifip being a pair of differential signals on the I channel. The amplifier circuit 220-2 on the Q channel may receive the frequency-converted signals being a pair of differential signals from the mixer 230, and process the frequency-converted signals according to a second gain in order to generate multiple second amplification signals ifqn and ifqp being a pair of differential signals on the Q channel.

The ADC 280 may receive the second amplification signals from the amplifier circuits 220-1 and 220-2, and convert the second amplification signals from analog signals to digital signals. The DSP 290 may receive the digital signals from the ADC 280, and process the digital signals for calibrating the IQ imbalance.

The compensation circuit 250 may be coupled to an output terminal of the amplifier circuit 210, and may provide an impedance at the output terminal of the amplifier circuit 210, wherein the impedance is a variable impedance (i.e., the impedance value can be adjusted dynamically). The controller circuit 260 may be coupled to the compensation circuit 250 and the amplifier circuits 220-1 and 220-2, and may control the compensation circuit 250 to correspondingly adjust the impedance provided at the output terminal of the amplifier circuit 210 in response to adjustment of the second gain.

According to an embodiment of the present invention, the amplifier circuits 220-1 and 220-2 may respectively include multiple signal input paths for receiving the frequency-converted signals from the mixer 230, and multiple resistors configured on the signal input paths. For example, the amplifier circuits 220-1 and 220-2 may respectively include a pair of first signal input paths with configured resistors R1ₐ, a pair of second signal input paths with configured resistors R1_{b}, and a pair of third signal input paths with configured resistors R1_{c}, wherein the resistors R1ₐ, R1_{b}, and R1_{c} have different resistance values. The amplifier circuits 220-1 and 220-2 may respectively receive the frequency-converted signals from the mixer 230 via a pair of signal input paths.

According to an embodiment of the present invention, the compensation circuit 250 may include multiple impedance control paths, such as impedance control paths 251, 252, and 253. The impedance control paths 251, 252, and 253 may provide different impedances at the output terminal of the amplifier circuit 210. According to an embodiment of the present invention, the compensation circuit 250 may include multiple circuit sub-units respectively configured on the impedance control paths. Each circuit sub-unit may be coupled to the output terminal of the amplifier circuit 210, and may include at least one of a resistor and a capacitor. In addition, each circuit sub-unit may generate different impedances at the output terminal of the amplifier circuit 210.

According to an embodiment of the present invention, the controller circuit 260 may adjust the second gain by switching the signal input paths of the amplifier circuits 220-1 and 220-2. Similarly, the controller circuit 260 may adjust the impedance at the output terminal of the amplifier circuit 210 by switching the impedance control paths of the compensation circuit 250.

In addition, in embodiments of the present invention, a corresponding relationship exists between the signal input paths and the impedance control paths (e.g., a one-to-one corresponding relationship, but the present invention is not limited thereto). When the signal input paths of the amplifier circuits 220-1 and 220-2 are switched, the controller circuit 260 may correspondingly adjust the impedance control paths.

For example, the pair of first signal input paths of the amplifier circuits 220-1 and 220-2 may correspond to the impedance control path 251, the pair of second signal input paths of the amplifier circuits 220-1 and 220-2 may correspond to the impedance control path 252, and the pair of third signal input paths of the amplifier circuits 220-1 and 220-2 may correspond to the impedance control path 253. When the controller circuit 260 switches the signal input paths of the amplifier circuits 220-1 and 220-2 from the pair of first signal input paths to the pair of second signal input paths, the controller circuit 260 may correspondingly switch the path for providing the impedance at the output terminal of the amplifier circuit 210 within the compensation circuit 250 from the impedance control path 251 to the impedance control path 252.

According to an embodiment of the present invention, the amplifier circuits 220-1 and 220-2 may include multiple switch devices respectively configured on the signal input paths, and the controller circuit 260 may switch the signal input paths by controlling states of the switch devices. For example, the controller circuit 260 may utilize a control signal REG_TIA1 to turn off switch devices on the first signal input paths, and simultaneously utilize control signals REG_TIA2 and REG_TIA3 to turn on switch devices on the second signal input paths and the third signal input paths, in order to control the amplifier circuits 220-1 and 220-2 to receive the frequency-converted signals from the mixer 230 via the first signal input paths. When the signal input paths of the amplifier circuits 220-1 and 220-2 are required to be switched from the first signal input paths to the second signal input paths, the controller circuit 260 may utilize the control signal REG_TIA2 to turn off the switch devices on the second signal input paths, and simultaneously utilize the control signals REG_TIA1 and REG_TIA3 to turn on the switch devices on the first signal input paths and the third signal input paths, in order to complete the signal input path switching.

Similarly, according to an embodiment of the present invention, the compensation circuit 250 may include multiple switch devices respectively configured on the impedance control paths, and the controller circuit 260 may switch the impedance control paths by controlling states of the switch devices. For example, the controller circuit 260 may utilize the control signal REG_TIA1 to turn off a switch device on the impedance control path 251, and simultaneously utilize the control signals REG_TIA2 and REG_TIA3 to turn on switch devices on the impedance control paths 252 and 253, in order to control the compensation circuit 250 to generate a corresponding impedance at the output terminal of the amplifier circuit 210 by the circuit sub-unit on the impedance control path 251. When the impedance control path is required to be switched from the impedance control path 251 to the impedance control path 252, the controller circuit 260 may utilize the control signal REG_TIA2 to turn off the switch device on the impedance control path 252, and simultaneously utilize the control signals REG_TIA1 and REG_TIA3 to turn on the switch devices on the impedance control paths 251 and 253, in order to complete the impedance control path switching.

According to an embodiment of the present invention, the second gain of the amplifier circuits 220-1 and 220-2 is associated with the resistance values of the resistors R1ₐ, R1_{b}, R1_{c}, and R2. When the amplifier circuits 220-1 and 220-2 receive and amplify the frequency-converted signals from the mixer 230 via the first signal input paths, the second gain is R2/R1ₐ (or a value obtained by performing a predetermined operation based on R2/R1ₐ). When the amplifier circuits 220-1 and 220-2 receive and amplify the frequency-converted signals from the mixer 230 via the second signal input paths or the third signal input paths, the second gain is R2/R1_{b} or R2/R1_{c} (or a value obtained by performing a predetermined operation based on R2/R1_{b} or R2/R1_{c}).

According to an embodiment of the present invention, switching the resistor R1 (i.e., the resistors R1ₐ, R1_{b}, and R1_{c}) of the amplifier circuits 220-1 and 220-2 may affect the impedance seen from the amplifier circuit 210 toward the mixer 230. As a result, when the resistor R1 of the amplifier circuits 220-1 and 220-2 is switched, the compensation circuit 250 provides an additional compensation path to compensate for the impedance and phase difference caused by resistor switching. In this way, even if the receiver circuit 200 only performs the pre-calibration for a specific gain level to obtain parameters required for calibrating IQ imbalance in the pre-calibration mode, when the receiver circuit 200 operates in the reception mode, the amplifier circuits 220-1 and 220-2 can operate at other gain levels and apply the parameters obtained in the pre-calibration mode to successfully calibrate the IQ imbalance, which can maintain good image rejection ratio when the amplifier gain is adjusted.

Specifically, assume that in the pre-calibration mode, the receiver circuit 200 only performs the pre-calibration for a first level of the second gain (e.g., R2/R1ₐ), and does not perform the pre-calibration for other levels of the second gain. As a result, only the optimal parameters (e.g., parameters that optimize the IQ imbalance calibration result or the image rejection ratio) estimated at the first level are obtained in the pre-calibration mode, and parameters required for calibrating the IQ imbalance at other levels of the second gain will not be obtained.

In embodiments of the present invention, when the receiver circuit 200 requires to set the second gain as a second level in the reception mode, since the compensation circuit 250 provides an additional compensation path, the impedance seen from the amplifier circuit 210 toward the mixer 230 may remain constant or nearly constant (i.e., may be identical or nearly identical to the impedance when the second gain is set as the first level in the pre-calibration mode), thereby compensating for the IQ imbalance caused by gain adjustment. In this way, even if the receiver circuit 200 applies the parameters corresponding to the first gain level while operating in the second gain level or other gain levels, the IQ imbalance can still be successfully calibrated, and an image rejection ratio as good as that of the first gain level can be achieved.

According to another embodiment of the present invention, as shown by dotted lines in FIG. 2, the controller circuit 260 may be further coupled to the amplifier circuit 210, and may control the compensation circuit 250 to correspondingly adjust the impedance provided at the output terminal of the amplifier circuit 210 in response to adjustment of the first gain. For example, the first gain may include multiple setting values, and the controller circuit 260 may adjust the first gain by switching the multiple setting values.

According to an embodiment of the present invention, the first gain may at least include a first setting value and a second setting value. The compensation circuit 250 may at least include a first impedance control path corresponding to the first setting value and a second impedance control path corresponding to the second setting value. When a value of the first gain is switched from the first setting value to the second setting value, the controller circuit 260 may correspondingly switch the path for providing the impedance in the compensation circuit 250 from the first impedance control path to the second impedance control path.

Since operations of correspondingly adjusting the impedance provided at the output terminal of the amplifier circuit 210 performed in response to adjustment of the first gain are similar to those performed in response to adjustment of the second gain, those skilled in the art will be able to derive the corresponding operations performed by the controller circuit 260 to compensate for the IQ imbalance caused by the first gain adjustment based on the above descriptions, and detailed descriptions are omitted here.

It should be noted that operations of compensating for IQ imbalance caused by gain adjustment through the compensation circuit 250 are not limited to gain adjustment of a single amplifier circuit, but can also be applied to gain adjustment of multiple amplifier circuits. That is, in embodiments of the present invention, the compensation circuit 250 may not only provide the impedance compensation for gain adjustment of a single amplifier circuit, but may also provide the impedance compensation for gain adjustment of multiple amplifier circuits.

In addition, although only a single-stage amplifier circuit is illustrated before and after the mixer 130/230 in FIGS. 1 and 2 , the present invention is not limited thereto. In an embodiment of the present invention, multiple-stage amplifier circuits may be included between the antenna and the mixer 130/230, and multiple-stage amplifier circuits may also be included between the mixer 130/230 and the ADC 180/280. In embodiments of the present invention, the compensation circuit 150/250 can be effectively utilized or controlled to provide impedance compensation corresponding to gain adjustment of any amplifier circuit.

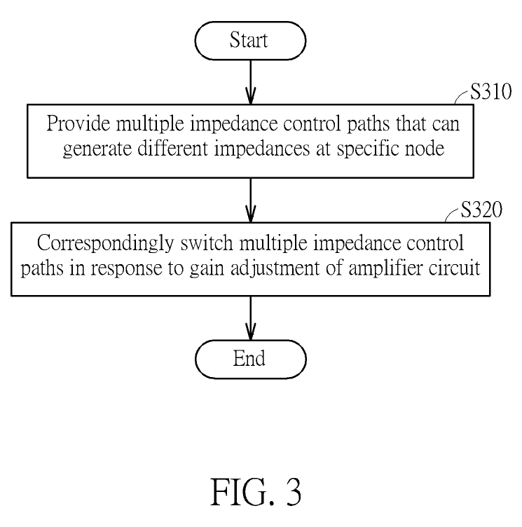

FIG. 3 is a flow chart of a method of compensating for IQ imbalance in a receiver circuit according to an embodiment of the present invention. The method may include the following steps.

In Step S310, multiple impedance control paths that can generate different impedances are provided at a specific node. According to an embodiment of the present invention, the specific node may be a node where the impedance correspondingly changes due to gain adjustment of an amplifier circuit.

In Step S320, the multiple impedance control paths are correspondingly switched in response to the gain adjustment of the amplifier circuit.

In summary, the present invention proposes a compensation circuit and an associated method capable of effectively compensating for IQ imbalance. By compensating for the IQ imbalance caused by gain adjustment, a good image rejection ratio can be maintained, which allows the receiver circuit to freely adjust the gain of the amplifier circuits in the reception mode without the image rejection ratio being degraded due to gain adjustment. By applying the compensation circuit and the method proposed by the present invention, even if the receiver circuit adjusts the gain of the amplifier circuits, the IQ imbalance can be compensated for without increasing the number of calibration operations. As a result, the flexibility of adjusting the amplifier gain is preserved, effectively solving the above-mentioned issues.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A receiver circuit, comprising:
a first amplifier circuit, arranged to process a reception signal according to a first gain in order to generate a first amplification signal;
a mixer, arranged to receive the first amplification signal, and perform a frequency conversion operation upon the first amplification signal according to an oscillation signal in order to generate a frequency-converted signal;
a second amplifier circuit, arranged to receive the frequency-converted signal, and process the frequency-converted signal according to a second gain in order to generate a second amplification signal;
a compensation circuit, coupled to an output terminal of the first amplifier circuit, and arranged to provide an impedance at the output terminal of the first amplifier circuit, wherein the impedance is a variable impedance; and
a controller circuit, coupled to the compensation circuit and the second amplifier circuit, and arranged to control the compensation circuit to correspondingly adjust the impedance in response to an adjustment of the second gain.

2. The receiver circuit of claim 1, wherein the second amplifier circuit comprises multiple signal input paths for receiving the frequency-converted signal from the mixer, and the controller circuit switches the multiple signal input paths to adjust the second gain.

3. The receiver circuit of claim 2, wherein the second amplifier circuit further comprises multiple resistors respectively configured on the multiple signal input paths, and the multiple resistors have different respective resistance values.

4. The receiver circuit of claim 3, wherein the second amplifier circuit further comprises multiple switch devices respectively configured on the multiple signal input paths, and the controller circuit switches the multiple signal input paths by controlling states of the multiple switch devices.

5. The receiver circuit of claim 1, wherein the compensation circuit comprises multiple impedance control paths, and the controller circuit adjusts the impedance by switching the multiple impedance control paths.

6. The receiver circuit of claim 5, wherein the compensation circuit further comprises multiple circuit sub-units respectively configured on the multiple impedance control paths, and the multiple circuit sub-units are coupled to the output terminal of the first amplifier circuit, and generate different respective impedances at the output terminal.

7. The receiver circuit of claim 6, wherein each of the multiple circuit sub-units comprises at least one of a resistor and a capacitor; the compensation circuit further comprises multiple switch devices respectively configured on the multiple impedance control paths; and the controller circuit switches the multiple impedance control paths by controlling states of the multiple switch devices.

8. The receiver circuit of claim 1, wherein a signal input path for receiving the frequency-converted signal from the mixer within the second amplifier circuit at least comprises a first signal input path and a second signal input path; a path for providing the impedance within the compensation circuit at least comprises a first impedance control path corresponding to the first signal input path and a second impedance control path corresponding to the second signal input path; and when the signal input path is switched from the first signal input path to the second signal input path, the controller circuit correspondingly switches the path from the first impedance control path to the second impedance control path.

9. A receiver circuit, comprising:
a first amplifier circuit, arranged to process a reception signal according to a first gain in order to generate a first amplification signal;
a mixer, arranged to receive the first amplification signal, and perform a frequency conversion operation upon the first amplification signal according to an oscillation signal in order to generate a frequency-converted signal;
a second amplifier circuit, arranged to receive the frequency-converted signal, and process the frequency-converted signal according to a second gain in order to generate a second amplification signal;
a compensation circuit, coupled to an output terminal of the first amplifier circuit, and arranged to provide an impedance at the output terminal of the first amplifier circuit, wherein the impedance is a variable impedance; and
a controller circuit, coupled to the first amplifier circuit, the compensation circuit, and the second amplifier circuit, and arranged to control the compensation circuit to correspondingly adjust the impedance in response to an adjustment of the first gain or an adjustment of the second gain.

10. The receiver circuit of claim 9, wherein the first gain comprises multiple setting values, and the controller circuit switches the multiple setting values to adjust the first gain.

11. The receiver circuit of claim 9, wherein the second amplifier circuit comprises multiple signal input paths for receiving the frequency-converted signal from the mixer, and the controller circuit switches the multiple signal input paths to adjust the second gain.

12. The receiver circuit of claim 11, wherein the second amplifier circuit further comprises multiple resistors respectively configured on the multiple signal input paths, and the multiple resistors have different respective resistance values.

13. The receiver circuit of claim 12, wherein the second amplifier circuit further comprises multiple switch devices respectively configured on the multiple signal input paths, and the controller circuit switches the multiple signal input paths by controlling states of the multiple switch devices.

14. The receiver circuit of claim 9, wherein the compensation circuit comprises multiple impedance control paths, and the controller circuit switches the multiple impedance control paths to adjust the impedance.

15. The receiver circuit of claim 14, wherein the compensation further comprises multiple circuit sub-units respectively configured on the multiple impedance control paths, and the multiple circuit sub-units are coupled to the output terminal of the first amplifier circuit, and generate different respective impedances at the output terminal.

16. The receiver circuit of claim 15, wherein each of the multiple circuit sub-units comprises at least one of a resistor and a capacitor; the compensation circuit further comprises multiple switch devices respectively configured on the multiple impedance control paths; and the controller circuit switches the multiple impedance control paths by controlling states of the multiple switch devices.

17. The receiver circuit of claim 9, wherein the first gain at least comprises a first setting value and a second setting value; a path for providing the impedance within the compensation circuit at least comprises a first impedance control path corresponding to the first setting value and a second impedance control path corresponding to the second setting value; and when the first gain is switched from the first setting value to the second setting value, the controller circuit correspondingly switches the path from the first impedance control path to the second impedance control path.

18. The receiver circuit of claim 9, wherein a signal input path for receiving the frequency-converted signal from the mixer within the second amplifier circuit at least comprises a first signal input path and a second signal input path; a path for providing the impedance within the compensation circuit at least comprises a first impedance control path corresponding to the first signal input path and a second impedance control path corresponding to the second impedance control path; and when the signal input path is switched from the first signal input path to the second signal input path, the controller circuit correspondingly switches the path from the first impedance control path to the second impedance control path.
